(19) United States
(12) Patent Application Publication
(10) Pub. No.: US 2010/0133698 A1
(43) Pub. Date: Jun. 3, 2010

(54) SEMICONDUCTOR DEVICE AND METHOD OF MANUFACTURING SEMICONDUCTOR DEVICE

(75) Inventor: Naoto KUROSAWA, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kanagawa (JP)

(21) Appl. No.: 12/619,063

(22) Filed: Nov. 16, 2009

(30) Foreign Application Priority Data
Dec. 1, 2008 (JP) 2008-306294

(51) Int. Cl. H01L 23/48; H01L 21/768

(52) U.S. Cl. 257/774; 438/700; 257/E23.011; 257/E21.585

(57) ABSTRACT

A method of manufacturing a semiconductor device which enables reduction of material costs and manufacturing costs of the semiconductor device includes forming a silicon cermet film, forming a protective film that protects the silicon cermet film, making a contact hole by plasma etching of the protective film. In this method, an etching detection layer for detecting an end point of plasma etching is formed in contact with the protective film, at least one of the protective film and the etching detection layer contains an element not common to both of the protective film and the etching detection layer, and an end point of plasma etching of the protective film is detected based on plasma emission of the element not common to the both when making the contact hole.

### BACKGROUND

1. Field of the Invention

The present invention relates to a semiconductor device and a method of manufacturing the same. Particularly, the present invention relates to a semiconductor device in which a stable high resistance value is obtained and a method of manufacturing the same.

2. Description of Related Art

As a semiconductor chip of an analog integrated circuit that handles a high-frequency signal, such as a high-frequency power amplifier and a high-frequency antenna switch, a monolithic microwave integrated circuit (MMIC) in which elements such as a transistor, an inductor, a capacitor and a resistor are formed on one chip is used in order to meet the demand for higher integration.

As a transistor formed on a semiconductor chip, one of the followings is used: a III-V group compound semiconductor metal-semiconductor field-effect transistor (MESFET); a transistor called a high electron mobility transistor (HEMT) in which high-frequency characteristics and noise characteristics of MESFET are improved (hereinafter, MESFET and HEMT are sometimes collectively referred to as FET); and a heterojunction bipolar transistor (HBT).

As a resistor formed on a semiconductor chip, a silicon cermet film such as TaSiO₂ in which high sheet resistance can be obtained, for example, is used in order to meet the demand for higher integration of a semiconductor element. The thickness of the silicon cermet film needs to be about 100 nm to 300 nm so as to obtain high sheet resistance.

However, during a manufacturing process, there have been cases where a silicon cermet material is easily etched by hydrofluoric acid, fluorine gas, chlorine gas or the like when making a contact hole for connecting a transistor such as MSFET, HEMT or HBT and a silicon cermet film by an electrode wiring such as Au or Al.

For the above reason, the contact resistance between the electrode wiring and the silicon cermet film becomes abnormally high, which causes a failure to obtain a normal resistance value in some cases. Further, due to a significant decrease in the contact area between the electrode wiring and the silicon cermet film, local concentration of a current and an electric field occurs, which causes degradation of reliability in some cases.

FIG. 6 is a cross-section view of a semiconductor device disclosed in Japanese Unexamined Patent Application Publication No. 2003-163270. A semiconductor device 25 includes a resistor film (silicon cermet film) 21 made of TaSiO₂ that is formed on a first insulating film 19 on a substrate 18, and a second insulating film 20 that covers the resistor film 21 and has a contact hole 23 for passing an electric current. The semiconductor device 25 further includes a first low-resistance metal film 22 that is formed in contact with the silicon cermet film 21 and at least covers the contact hole 23, and a second low-resistance metal film 24 that is connected to the first low-resistance metal film 22 through the contact hole 23 (which is a low-resistance metal filling the contact hole), which are placed on top of each other. In the semiconductor device 25 disclosed in Japanese Unexamined Patent Application Publication No. 2003-163270, gold is used as a material of at least one of the low-resistance metal films 22 and 24.

In the semiconductor device 25 disclosed in Japanese Unexamined Patent Application Publication No. 2003-163270, because the first low-resistance metal film 22 made of Au is formed on the silicon cermet film 21 made of TaSiO₂, it is possible to make the contact hole 23 without directly etching the silicon cermet film 21. Further, because the etching selectivity of the insulating film and Au is high, it is possible to perform adequately large over-etching and thereby make the contact hole stably.

### SUMMARY

However, in the semiconductor device and the method of manufacturing the semiconductor device disclosed in Japanese Unexamined Patent Application Publication No. 2003-163270, gold is used for the low-resistance metal film, and a photoresist (PR) step and a formation step for forming the low-resistance metal film are required, which significantly increases material costs and manufacturing costs.

A first exemplary aspect of an embodiment of the present invention is a method of manufacturing a semiconductor device including forming a silicon cermet film, forming a protective film that protects the silicon cermet film, and making a contact hole by plasma etching of the protective film. In this method, an etching detection layer for detecting an end point of plasma etching is formed in contact with the protective film, at least one of the protective film and the etching detection layer contains an element not common to both of the protective film and the etching detection layer, and an end point of etching of the protective film is detected based on plasma emission of the element not common to the both when making the contact hole.

By using the method of manufacturing a semiconductor device according to the exemplary embodiment, it is possible to eliminate the need to form a low-resistance film such as gold on the silicon cermet film and also possible to make a contact hole accurately because of its capability of detecting the etching end point, thereby enabling reduction of material costs and manufacturing costs.

A second exemplary aspect of an embodiment of the present invention is a semiconductor device including a silicon cermet film, a protective film that protects the silicon cermet film, an etching detection layer that is formed in contact with the protective film, and a wiring that fills a contact hole made in the protective film and is connected to the silicon cermet film. In this semiconductor device, at least one of the protective film and the etching detection layer contains an element not common to both of the protective film and the etching detection layer.

In this structure, it is possible to eliminate the need to form a low-resistance film such as gold on the silicon cermet film and also possible to make a contact hole accurately because of its capability of detecting the etching end point, thereby enabling reduction of material costs and manufacturing costs.

According to the exemplary aspects of an embodiment of the present invention described above, it is possible to provide a semiconductor device and a method of manufacturing the same which enable reduction of material costs and manufacturing costs of the semiconductor device.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a cross-section view of a semiconductor device according to a first exemplary embodiment;

FIG. 2 is a cross-section view of a semiconductor device according to a second exemplary embodiment;

FIGS. 3A to 3F are cross-section views of a method of manufacturing a semiconductor device according to the first exemplary embodiment;

FIGS. 4A to 4E are cross-section views of a method of manufacturing a semiconductor device according to the second exemplary embodiment;

FIG. 5 is a view showing an emission intensity (in a waveband of 421 nm) in the case of using an SiN film as a protective film and an SiO₂ film as an etching detection layer; and

FIG. 6 is a cross-section view of a semiconductor device according to related art.

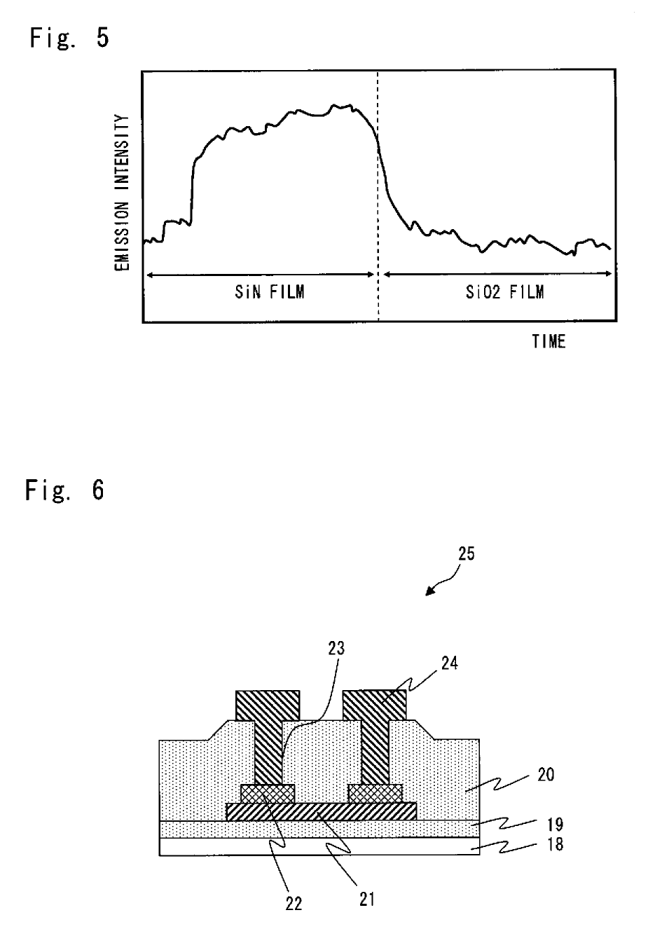

### DETAILED DESCRIPTION OF THE EXEMPLARY EMBODIMENTS

Exemplary embodiments of the present invention are described hereinafter with reference to the drawings.

The outline of the present invention, which is described in detail as exemplary embodiments later, is described firstly.

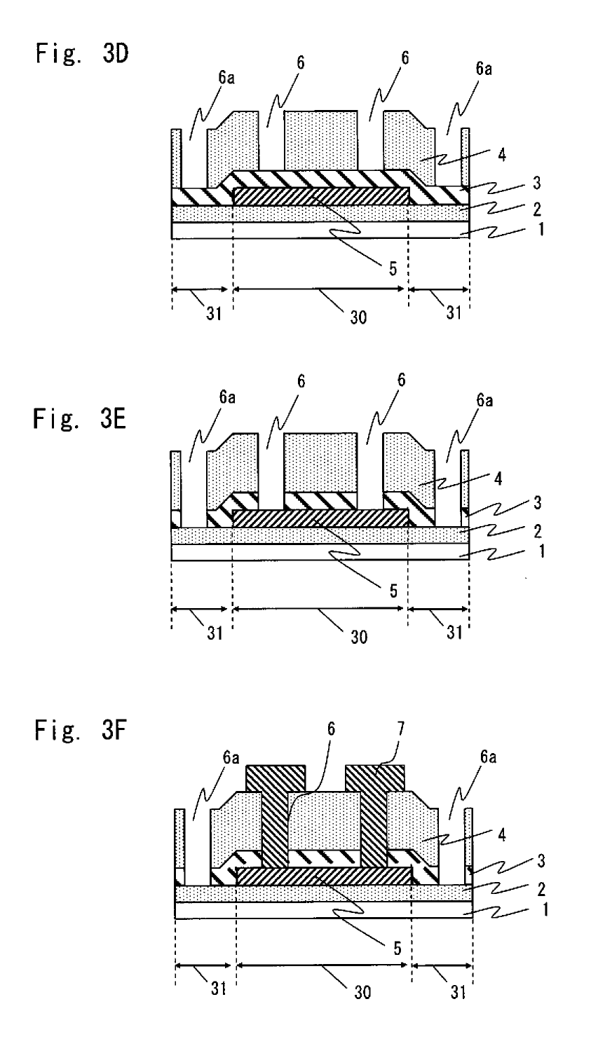

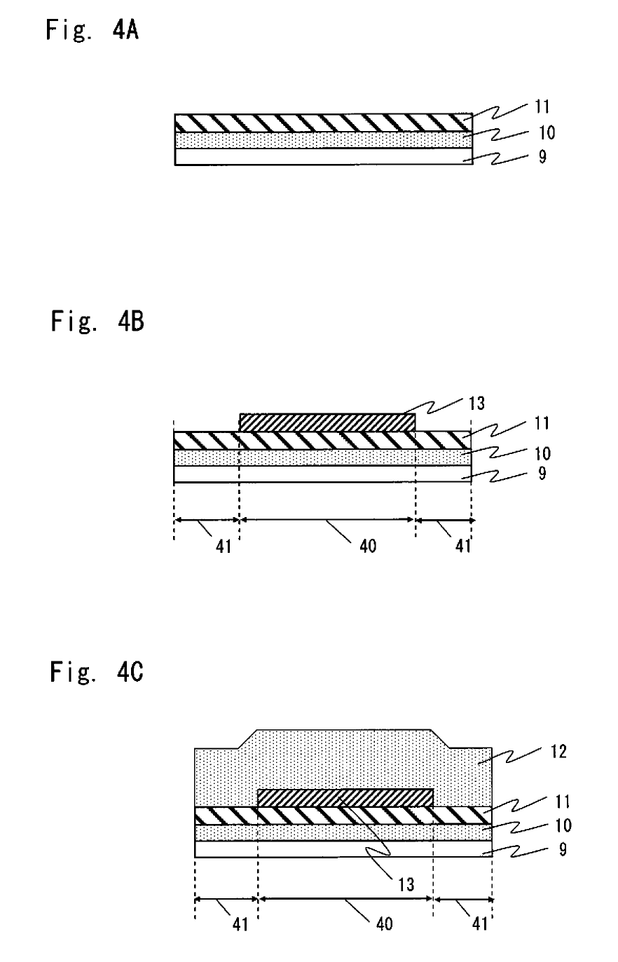

A method of manufacturing a semiconductor device according to an exemplary embodiment includes the following steps (cf. FIGS. 3A to 3F, 4A to 4E): a step of forming a silicon cermet film 5 or 13 (FIG. 3A, FIG. 4B); a step of forming a protective film 4 or 12 that protects the silicon cermet film 5 or 13 (FIG. 3C, FIG. 4C); and an opening step of making a contact hole 6 or 14 by plasma-etching the protective film 4 or 12 (FIG. 3D, FIG. 4D).

Further, an etching detection layer 3 or 11 for detecting the end point of etching in the opening step is formed in contact with the protective film 4 or 12. At least one of the protective film 4 or 12 and the etching detection layer 3 or 11 contains an element that is not common to both of the protective film and the etching detection layer (which is an element different from an element common to the both).

Furthermore, in the opening step, the end point of etching of the protective film 4 or 12 is detected based on plasma emission of the element that is not common to the both. Detecting the end point of etching of the protective film 4 or 12 based on plasma emission refers to the following cases.

The case where the protective film 4 or 12 contains the element that is not common to the both (the protective film 4 or 12 and the etching detection layer 3 or 11).

In this case, plasma emission of the element that is not common to the both is detected during etching of the protective film 4 or 12. When etching reaches the etching detection layer 3 or 11, plasma emission of the element that is not common to the both is extinguished (or attenuated), the timing of which corresponds to the end point of etching.

The case where the etching detection layer 3 or 11 contains the element that is not common to the both (the protective film 4 or 12 and the etching detection layer 3 or 11).

In this case, plasma emission of the element that is not common to the both is monitored during etching of the protective film 4 or 12. Because the protective film 4 or 12 does not contain the element that is not common to the both, the element that is not common to the both is not detected during etching of the protective film 4 or 12. When etching reaches the etching detection layer 3 or 11, plasma emission of the element that is not common to the both is detected, the timing of which corresponds to the end point of etching.

The case where both of the protective film 4 or 12 and the etching detection layer 3 or 11 contains the element that is not common to the both.

In this case, the end point of etching is detected by monitoring the element contained only in the protective film 4 or 12 or the element contained only in the etching detection layer 3 or 11.

Specifically, in the case of detecting the end point of etching by using the element contained only in the protective film 4 or 12, plasma emission of the element contained only in the protective film 4 or 12 is detected during etching of the protective film 4 or 12. When etching reaches the etching detection layer 3 or 11, the detected plasma emission is extinguished (or attenuated), the timing of which corresponds to the end point of etching.

On the other hand, in the case of detecting the end point of etching by using the element contained only in the etching detection layer 3 or 11, plasma emission of the element contained only in the etching detection layer 3 or 11 is monitored during etching of the protective film 4 or 12. Because the protective film 4 or 12 does not contain the element that is contained only in the etching detection layer 3 or 11, the element is not detected during etching of the protective film 4 or 12. When etching reaches the etching detection layer 3 or 11, plasma emission of the element that is contained only in the etching detection layer 3 or 11 is detected, the timing of which corresponds to the end point of etching.

By using the method of manufacturing a semiconductor device according to the exemplary embodiment, it is possible to eliminate the need to form a low-resistance film such as gold on the silicon cermet film and also possible to make a contact hole accurately because of its capability of detecting the etching end point, thereby enabling reduction of material costs and manufacturing costs.

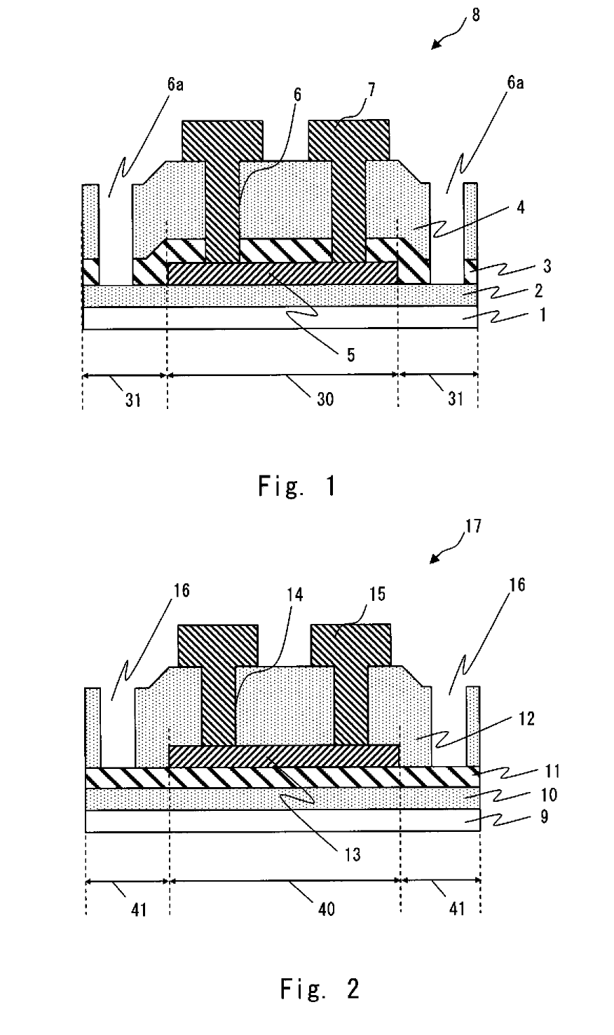

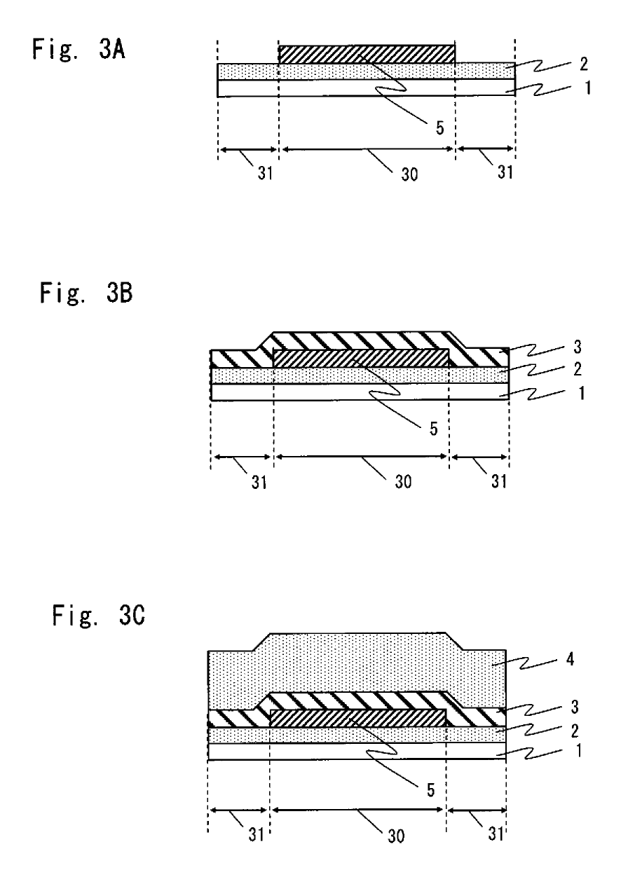

A semiconductor device according to an exemplary embodiment of the present invention is described next (cf. FIGS. 1 and 2).

A semiconductor device according to an exemplary embodiment includes a silicon cermet film 5 or 13, a protective film 4 or 12 that protects the silicon cermet film 5 or 13, and an etching detection layer 3 or 11 that is formed in contact with the protective film 4 or 12. The semiconductor device further includes a wiring 7 or 15 that fills a contact hole 6 or 14 made in the protective film 4 or 12 and is connected to the silicon cermet film 5 or 13. At least one of the protective film 4 or 12 and the etching detection layer 3 or 11 contains an element that is not common to both of the protective film and the etching detection layer.

A semiconductor device and a method of manufacturing a semiconductor device according to an exemplary embodiment of the present invention are described hereinafter in detail as a first exemplary embodiment and a second exemplary embodiment.

### First Exemplary Embodiment

The first exemplary embodiment of the present invention is described hereinafter with reference to the drawings.

FIG. 1 is a cross-section view of a semiconductor device according to the first exemplary embodiment. FIGS. 3A to 3F are cross-section views of a method of manufacturing a semiconductor device according to the first exemplary embodiment. The method of manufacturing a semiconductor device according to the first exemplary embodiment is described firstly with reference to FIGS. 3A to 3F.

The method of manufacturing a semiconductor device according to the exemplary embodiment includes a first step of forming a silicon cermet film 5 on an insulating film 2 on a substrate 1 in a first region 30 (FIG. 3A).

The substrate 1 is made of GaAs, which is a semiconductor material, for example. Alternatively, the substrate 1 may be made of Si, InP, GaN, SiC or the like. The insulating film 2 has a composition containing silicon and at least one kind of element selected from oxygen, nitrogen and carbon, for example.

The silicon cermet film 5, which is a resistor material film, is a TaSiO₂ film, for example. Alternatively, the silicon cermet film 5 may be made of a material with a composition containing silicon, a metal element and at least one kind of element selected from oxygen, nitrogen and carbon. The metal element used therein is Ta, Ti, W, Mo or Cr, for example.

The method of manufacturing a semiconductor device according to the exemplary embodiment further includes a second step of forming an etching detection layer 3 on the silicon cermet film 5 in the first region 30 and on the insulating film 2 in a second region 31 where the silicon cermet film 5 is not formed (FIG. 3B).

The first region 30 is a part of the substrate surface in which the silicon cermet film 5 is formed. The second region 31 is a part of the substrate surface in which the silicon cermet film 5 is not formed. Thus, in the second step, the etching detection layer 3 is formed to cover the silicon cermet film 5.

The etching detection layer 3 is made of SiO₂, for example. The etching detection layer 3 is a film containing an element that is not contained in a protective film 4, which is described later, and it is typically a film with a composition containing silicon and at least one kind of element selected from oxygen, nitrogen and carbon.

The method of manufacturing a semiconductor device according to the exemplary embodiment further includes a third step of forming a protective film 4 containing an element that is not contained in the etching detection layer 3 on the etching detection layer 3 in the first region 30 and the second region 31 (FIG. 3C).

The protective film 4 is made of SiN, for example. The protective film 4 is a film containing an element that is not contained in the etching detection layer 3, and it is typically a film with a composition containing silicon and at least one kind of element selected from oxygen, nitrogen and carbon.

The method of manufacturing a semiconductor device according to the exemplary embodiment further includes a fourth step of making a contact hole 6 in the protective film 4 in the first region 30 and an etching detection opening 6a in the protective film 4 in the second region 31, respectively down to the etching detection layer 3 (FIG. 3D). The method further includes a fifth step of making the contact hole 6 in the etching detection layer 3 in the first region 30 down to the silicon cermet film 5 (FIG. 3E).

When making the contact hole 6 by dry-etching the protective film 4 in the fourth step, the end point of etching is detected by using emission spectrometry. Specifically, a waveband in which an optical change occurs at the end point is detected and analyzed by spectrometry of plasma light during etching reaction, thereby detecting an optimum end point. A waveband of plasma light during etching reaction has multiple discrete values determined by quantum mechanics, and it is light with an intrinsic wavelength determined by each element (bright-line spectrum).

In this exemplary embodiment, an insulating film containing an element that is not contained in the protective film 4 is used as the etching detection layer 3 between the protective film 4 and the silicon cermet film 5, thereby allowing a change in emission intensity in the waveband where an optical change occurs.

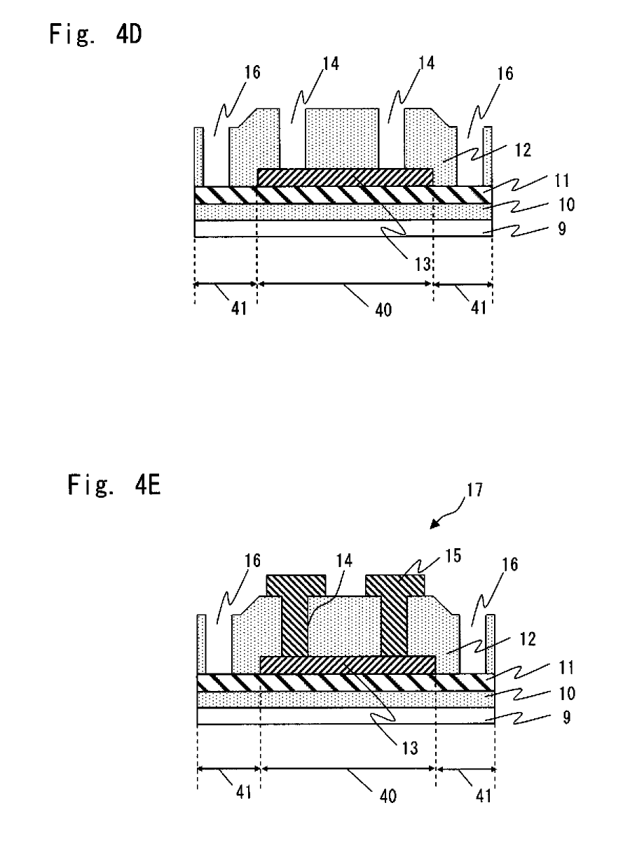

FIG. 5 shows the emission intensity (N element) detected in a certain waveband (421 nm) in the case of using an SiN film as the protective film 4 and an SiO₂ film as the etching detection layer 3, for example. As shown in FIG. 5, the emission intensity is high when etching the SiN film (the protective film 4) and it is low when etching the SiO₂ film (the etching detection layer 3). Thus, the timing when the emission intensity changes corresponds to the end point of etching (the point when reaching the etching detection layer 3).

In this case, plasma emission may be monitored in accordance with the emission intensity of oxygen. If plasma emission is monitored in accordance with the emission intensity of oxygen, plasma emission is not obtained while etching the protective film 4. On the other hand, plasma emission of an oxygen atom is detected at the time when etching reaches the etching detection layer 3. The timing corresponds to the end point of etching.

Further, in the fifth step, the contact hole 6 is formed in the etching detection layer 3 until reaching the silicon cermet film 5. The amount of etching in this step is determined based on the film thickness (which is known) of the etching detection layer 3, for example. The film thickness of the etching detection layer 3 is less than the film thickness of the protective film 4. It is thus possible to make the contact hole more accurately when detecting the end point of etching by forming the etching detection layer 3 and then estimating the amount of etching with use of the film thickness (which is known) of the etching detection layer 3 than when estimating the amount of etching with use of the thickness of the protective film 4 without forming the etching detection layer 3.

Therefore, by using the method of manufacturing a semiconductor device according to the exemplary embodiment, it is possible to detect the end point of etching during dry etching for making the contact hole and thereby reduce the amount of over-etching of the silicon cermet film 5.

Further, it is preferred that the thickness of the etching detection layer 3 is less than the thickness of the silicon cermet film 5 if an etching rate ratio between TaSiO₂ and SiO₂ is about 1:2 and the amount of over-etching is 50% to 100%. Specifically, when making a contact hole for passing an electric current, which is generally made by dry etching, it is necessary to perform adequately large over-etching for stabilization. At this time, it is often the case that the amount of over-etching is 50% to 100% with respect to the thickness of the etched film. If the thickness of the etching detection layer is less than the thickness of the silicon cermet film, it is possible to make the contact hole stably with consideration of the adequately large over-etching.

Furthermore, because the contact hole 6 for passing an electric current is made on the silicon cermet film 5, an opening area of the contact hole in a wafer plane is about 1% to 2%. In this case, it is difficult to obtain an emission intensity that is high enough to detect the end point of etching by using emission spectrometry. In view of this, the etching detection opening 6a is made in the region (the second region 31) where the silicon cermet film 5 is not formed, thereby increasing the emission intensity and allowing stable detection of the etching end point. The area of the etching detection opening 6a is preferably larger than the area of the opening of the contact hole 6.

The method of manufacturing a semiconductor device according to the exemplary embodiment further includes a sixth step of filling the contact hole 6 with a conducting material 7 (FIG. 3F). The conducting material 7 is introduced into the contact hole 6 so as to come into contact with the silicon cermet film 5 and serves as a wiring. As the conducting material 7, Al, Au or the like, for example, may be used.

Referring now to FIG. 1, a semiconductor device 8 according to the exemplary embodiment includes the substrate 1, the insulating film 2 that is formed on the substrate 1, and the silicon cermet film 5 that is formed on the insulating film 2 in the first region 30. The semiconductor device 8 according to the exemplary embodiment further includes the etching detection layer 3 that is formed on the silicon cermet film 5 in the first region 30 and on the insulating film 2 in the second region 31 where the silicon cermet film 5 is not formed, and the protective film 4 containing an element which is not contained in the etching detection layer 3, that is formed on the etching detection layer 3 in the first region 30 and the second region 31. The semiconductor device 8 according to the exemplary embodiment further includes the wiring 7 which fills the contact hole 6 that is made in the protective film 4 and the etching detection layer 3 in the first region 30 and is connected to the silicon cermet film 5, and the etching detection opening 6a that is made in the protective film 4 and the etching detection layer 3 in the second region 31.

According to the exemplary embodiment of the present invention described above, it is possible to provide a semiconductor device and a method of manufacturing the same which enable reduction of material costs and manufacturing costs of the semiconductor device.

### Second Exemplary Embodiment

A second exemplary embodiment of the present invention is described hereinafter with reference to the drawings.

FIG. 2 is a cross-section view of a semiconductor device according to the second exemplary embodiment. FIGS. 4A to 4E are cross-section views of a method of manufacturing a semiconductor device according to the second exemplary embodiment. The method of manufacturing a semiconductor device according to the second exemplary embodiment is described firstly with reference to FIGS. 4A to 4E.

The method of manufacturing a semiconductor device according to the exemplary embodiment includes a first step of forming an etching detection layer 11 on an insulating film 10 that is formed on a substrate 9 (FIG. 4A).

The substrate 9 is made of GaAs, which is a semiconductor material, for example. Alternatively, the substrate 9 may be made of Si, InP, GaN, SiC or the like. The insulating film 10 has a composition containing silicon and at least one kind of element selected from oxygen, nitrogen and carbon, for example.

The etching detection layer 11 is made of SiO₂, for example. The etching detection layer 11 is a film containing an element that is not contained in a protective film 12, which is described later, and it is typically a film with a composition containing silicon and at least one kind of element selected from oxygen, nitrogen and carbon.

The method of manufacturing a semiconductor device according to the exemplary embodiment further includes a second step of forming a silicon cermet film 13 on the etching detection layer 11 in a first region 40 (FIG. 4B).

The silicon cermet film 13, which is a resistor material film, is a TaSiO₂ film, for example. Alternatively, the silicon cermet film 13 may be made of a material with a composition containing silicon, a metal element and at least one kind of element selected from oxygen, nitrogen and carbon. The metal element used therein is Ta, Ti, W, Mo or Cr, for example.

The first region 40 is a part of the substrate surface in which the silicon cermet film 13 is formed. A second region 41 is a part of the substrate surface in which the silicon cermet film 13 is not formed.

The method of manufacturing a semiconductor device according to the exemplary embodiment further includes a third step of forming a protective film 12 containing an element that is not contained in the etching detection layer 11 on the silicon cermet film 13 in the first region 40 and on the etching detection layer 11 in the second region 41 where the silicon cermet film 13 is not formed (FIG. 4C).

The protective film 12 is made of SiN, for example. The protective film 12 is a film containing an element that is not contained in the etching detection layer 11, and it is typically a film with a composition containing silicon and at least one kind of element selected from oxygen, nitrogen and carbon.

The method of manufacturing a semiconductor device according to the exemplary embodiment further includes a fourth step of making a contact hole 14 in the protective film 12 in the first region 40 down to the silicon cermet film 13 in the first region 40 and making an etching detection opening 16 in the protective film 12 in the second region 41 down to the etching detection layer 11 in the second region 41 (FIG. 4D).

When making the contact hole 14 by dry-etching the protective film 12 in the fourth step, the end point of etching is detected by using emission spectrometry. Specifically, a waveband in which an optical change occurs at the end point is detected and analyzed by spectrometry of plasma light during etching reaction, thereby detecting an optimum end point. A waveband of plasma light during etching reaction has multiple discrete values determined by quantum mechanics, and it is light with an intrinsic wavelength determined by each element (bright-line spectrum).

In this exemplary embodiment, an insulating film containing an element that is not contained in the protective film 12 is used as the etching detection layer 11, thereby allowing a change in emission intensity in the waveband where an optical change occurs.

FIG. 5 shows the emission intensity detected in a certain waveband (421 nm) in the case of using an SiN film as the protective film 12 and an SiO₂ film as the etching detection layer 11, for example. As shown in FIG. 5, the emission intensity is high when etching the SiN film (the protective film 12) and it is low when etching the SiO₂ film (the etching detection layer 11). Thus, the timing when the emission intensity changes corresponds to the end point of etching (the point when reaching the etching detection layer 11).

In this case, plasma emission may be monitored in accordance with the emission intensity of oxygen. If plasma emission is monitored in accordance with the emission intensity of oxygen, plasma emission is not obtained while etching the protective film 12. On the other hand, plasma emission of an oxygen atom is detected at the time when etching reaches the etching detection layer 11. The timing corresponds to the end point of etching.

By using the above-described technique, it is possible to detect the end point of etching during dry etching for making the contact hole 14 and thereby reduce the amount of over-etching of the silicon cermet film 13. In this exemplary embodiment, the contact hole is formed down to the surface of the silicon cermet film 13 at the timing of detecting the end point of etching.

Furthermore, because the contact hole 14 for passing an electric current is made on the silicon cermet film 13, an opening area of the contact hole in a wafer plane is about 1% to 2%. In this case, it is difficult to obtain an emission intensity that is high enough to detect the end point of etching by using emission spectrometry. In view of this, the etching detection opening 16 is made in the region (the second region 41) where the silicon cermet film 13 is not formed, thereby increasing the emission intensity and allowing stable detection of the etching end point. The area of the etching detection opening 16 is preferably larger than the area of the opening of the contact hole 14.

The method of manufacturing a semiconductor device according to the exemplary embodiment further includes a fifth step of filling the contact hole 14 with a conducting material 15 (FIG. 4E). The conducting material 15 is introduced into the contact hole 14 so as to come into contact with the silicon cermet film 13 and serves as an electrode wiring. As the conducting material 15, Al, Au or the like, for example, may be used.

Referring now to FIG. 2, a semiconductor device 17 according to the exemplary embodiment includes the substrate 9, the insulating film 10 that is formed on the substrate 9, and the etching detection layer 11 that is formed on the insulating film 10. The semiconductor device 17 according to the exemplary embodiment further includes the silicon cermet film 13 that is formed on the etching detection layer 11 in the first region 40, and the protective film 12 containing an element which is not contained in the etching detection layer 11, that is formed on the silicon cermet film 13 in the first region 40 and on the etching detection layer 11 in the second region 41 where the silicon cermet film 13 is not formed. The semiconductor device 17 according to the exemplary embodiment further includes the wiring 15 which fills the contact hole 14 that is made in the protective film 12 in the first region 40 and is connected to the silicon cermet film 13, and the etching detection opening 16 that is made in the protective film 12 in the second region 41.

According to the exemplary embodiment of the present invention described above, it is possible to provide a semiconductor device and a method of manufacturing the same which enable reduction of material costs and manufacturing costs of the semiconductor device.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A method of manufacturing a semiconductor device comprising steps of:
forming a silicon cermet film;
forming a protective film that protects the silicon cermet film; and
making a contact hole by plasma etching of the protective film, wherein
an etching detection layer for detecting an end point of plasma etching when making the contact hole is formed in contact with the protective film,
at least one of the protective film and the etching detection layer contains an element not common to both of the protective film and the etching detection layer, and
an end point of plasma etching of the protective film is detected based on plasma emission of the element not common to the both when making the contact hole.

2. The method of manufacturing a semiconductor device according to claim 1, wherein
the silicon cermet film is formed on an insulating film on a substrate in a first region,
the etching detection layer is formed on the silicon cermet film in the first region and on the insulating film in a second region where the silicon cermet film is not formed,
the protective film is formed on the etching detection layer, and
the step of making the contact hole includes making a contact hole in the protective film in the first region and making an etching detection opening in the protective film in the second region, respectively down to the etching detection layer, and further making the contact hole in the etching detection layer in the first region down to the silicon cermet film.

3. The method of manufacturing a semiconductor device according to claim 2, wherein an area of the etching detection opening is larger than an area of an opening of the contact hole.

4. The method of manufacturing a semiconductor device according to claim 1, wherein
the etching detection layer is formed on an insulating film on a substrate,
the silicon cermet film is formed on the etching detection layer in a first region,
the protective film is formed on the silicon cermet film in the first region and on the etching detection layer in a second region where the silicon cermet film is not formed, and
the step of making the contact hole includes making a contact hole in the protective film in the first region down to the silicon cermet film in the first region and making an etching detection opening in the protective film in the second region down to the etching detection layer in the second region.

5. The method of manufacturing a semiconductor device according to claim 4, wherein an area of the etching detection opening is larger than an area of an opening of the contact hole.

6. The method of manufacturing a semiconductor device according to claim 1, wherein the etching detection layer contains SiO₂, and the protective film contains SiN.

7. The method of manufacturing a semiconductor device according to claim 1, wherein a thickness of the etching detection layer is less than a thickness of the silicon cermet film.

8. A semiconductor device comprising:
a silicon cermet film;
a protective film that protects the silicon cermet film;
an etching detection layer that is formed in contact with the protective film; and
a wiring that fills a contact hole made in the protective film and is connected to the silicon cermet film, wherein
at least one of the protective film and the etching detection layer contains an element not common to both of the protective film and the etching detection layer.

9. The semiconductor device according to claim 8, wherein
the silicon cermet film is formed on an insulating film on a substrate in a first region,
the etching detection layer is formed on the silicon cermet film in the first region and on the insulating film in a second region where the silicon cermet film is not formed,
the wiring fills the contact hole made in the protective film and the etching detection layer in the first region, and
the protective film and the etching detection layer in the second region has an etching detection opening.

10. The semiconductor device according to claim 8, wherein
the etching detection layer is formed on an insulating film on a substrate,
the silicon cermet film is formed on the etching detection layer in a first region,
the protective film is formed on the silicon cermet film in the first region and on the etching detection layer in a second region where the silicon cermet film is not formed,
the wiring fills the contact hole made in the protective film in the first region, and
the protective film in the second region has an etching detection opening.
